(19) United States
(12) Patent Application Publication
(10) Pub. No.: US 2026/0293550 A1
(43) Pub. Date: Sep. 24, 2026

(54) ETCHING METHOD

(71) Applicant: Resonac Corporation, Tokyo (JP)

(72) Inventor: Kazuma MATSUI, Tokyo (JP)

(73) Assignee: Resonac Corporation, Tokyo (JP)

(21) Appl. No.: 19/477,344

(22) PCT Filed: Dec. 3, 2024
(86) PCT No.: PCT/JP2024/042679

§ 371 Date: Oct. 21, 2025

(30) Foreign Application Priority Data
Dec. 4, 2023 (JP) 2023-204553
Dec. 12, 2023 (JP) 2023-209114

(51) Int. Cl. H10P 50/24; H10P 50/26; H10P 50/28

(52) U.S. Cl. CPC H10P 50/242; H10P 50/268; H10P 50/283

(57) ABSTRACT

There is provided an etching method capable of selectively etching an etching object in comparison to a non-etching object. The etching method includes an etching step of carrying out etching by bringing an etching gas containing an acid fluoride and a saturated fluorocarbon into contact with a member to be etched, which has an etching object which is an object to be etched by the etching gas and a non-etching object which is not an object to be etched by the etching gas, in a presence of a plasma, and selectively etching the etching object in comparison to the non-etching object. The etching object has a silicon-containing material, and the non-etching object has a carbon-containing material.

### TECHNICAL FIELD

The present disclosure relates to an etching method.

### BACKGROUND ART

In a manufacturing step for a semiconductor, there is a step of etching an etching object, which is an object to be etched by an etching gas, by plasma etching using an etching gas, thereby subjecting the etching object to microfabrication into a desired shape. In this etching, it is important to be able to selectively etch an etching object such as a silicon-containing material (i.e., etching selectivity) in comparison to a non-etching object such as a carbon-containing material (for example, a photoresist or a carbon mask), which is not an object to be etched by an etching gas. For example, PTL 1 discloses a technology of etching a silicon-containing material using an etching gas containing carbonyl fluoride.

### CITATION LIST

### Patent Literature

PTL 1: JP 6546889 B

### SUMMARY OF INVENTION

### Technical Problem

However, in the technology disclosed in PTL 1, a silicon-containing material may not be etched with excellent etching selectivity.

An object of the present disclosure is to provide an etching method capable of selectively etching an etching object having a silicon-containing material in comparison to a non-etching object having a carbon-containing material.

### Solution to Problem

To achieve the above object, one aspect of the present disclosure is as the following [1] to [6].

[1] An etching method including:
an etching step of carrying out etching by bringing an etching gas containing an acid fluoride and a saturated fluorocarbon into contact with a member to be etched, which has an etching object which is an object to be etched by the etching gas and a non-etching object which is not an object to be etched by the etching gas, in a presence of a plasma, and selectively etching the etching object in comparison to the non-etching object,
in which the etching object has a silicon-containing material, and the non-etching object has a carbon-containing material.

[2] The etching method according to [1], in which the carbon-containing material contains 20% by mass or more and 100% by mass or less of carbon.

[3] The etching method according to [1] or [2], in which the silicon-containing material contains silicon and germanium, and a total content of the silicon and the germanium, which are contained in the silicon-containing material, is 30% by mole or more.

[4] The etching method according to [1] or [2], in which the silicon-containing material is at least one of silicon oxide, silicon nitride, polysilicon, and silicon germanium.

[5] The etching method according to any one of [1] to [4], in which an etching selectivity ratio, which is a ratio of an etching rate of the silicon-containing material to an etching rate of the carbon-containing material, is 5 or more.

[6] The etching method according to any one of [1] to [5], in which the acid fluoride is at least one of carbonyl fluoride, oxalyl fluoride, and trifluoroacetyl fluoride.

### Advantageous Effects of Invention

According to the etching method according to the present disclosure, it is possible to selectively etching an etching object having a silicon-containing material in comparison to a non-etching object having a carbon-containing material.

### BRIEF DESCRIPTION OF DRAWINGS

FIG. 1 is a schematic view of an example of a plasma etching device for describing one embodiment of an etching method according to the present disclosure.

### DESCRIPTION OF EMBODIMENTS

One embodiment of the present disclosure will now be described. The embodiment is merely one example of the present disclosure, and the present disclosure is not limited to the embodiment. Various modifications or improvements can be made in the embodiment, and such modifications and improvements can be encompassed by the present disclosure.

An etching method according to the present embodiment includes an etching step of carrying out etching by bringing an etching gas containing an acid fluoride and a saturated fluorocarbon into contact with a member to be etched, which has an etching object which is an object to be etched by the etching gas and a non-etching object which is not an object to be etched by the etching gas, in a presence of a plasma, and selectively etching the etching object in comparison to the non-etching object, in which the etching object has a silicon-containing material, and the non-etching object has a carbon-containing material.

When the etching gas is brought into contact with a member to be etched, the acid fluoride in the etching gas reacts with silicon in the etching object, and thus the etching of the etching object proceeds. On the other hand, the non-etching object reacts with an oxygen atom or an oxygen-containing compound (active oxygen molecule, ozone, or the like) generated by the decomposition of the acid fluoride, and the etching proceeds.

However, when an acid fluoride and a saturated fluorocarbon are present together in the etching gas, carbon is supplied from the saturated fluorocarbon, and the oxygen-containing compound is captured, and thus the etching of the carbon-containing material is suppressed. Therefore the etching of the non-etching object hardly proceeds. As a result, according to the etching method according to the present embodiment, it is possible to selectively etch an etching object having a silicon-containing material, in comparison to a non-etching object having a carbon-containing material.

For example, the etching is capable of being carried out so that an etching selectivity ratio ([etching rate of silicon-containing material]/[etching rate of carbon-containing material]), which is a ratio of the etching rate of the silicon-containing material to the etching rate of the carbon-containing material, is 5 or more. In addition, from the viewpoint of more stably controlling the etching, the etching is capable of being carried out under an etching condition so that the etching selectivity ratio is 10 or more.

In the present disclosure, etching means removing a part or whole of an etching object contained in a member to be etched and then processing the member to be etched into a predetermined shape (for example, a three-dimensional shape) (for example, processing a film-shaped etching object made of a silicon-containing material contained in the member to be etched so that the film-shaped etching object has a predetermined film thickness), and means carrying out cleaning by removing a residue or a deposit formed of an etching object from a member to be etched.

The etching method according to the present embodiment can be used in the manufacture of a semiconductor element. More specifically, the method for manufacturing a semiconductor element according to the present embodiment is a method for manufacturing a semiconductor element, by which a semiconductor element is manufactured by using the etching method according to the present embodiment, in which the member to be etched is a semiconductor substrate having an etching object and a non-etching object, and the method includes removing at least a part of the etching object from the semiconductor substrate by etching.

Therefore, when the etching method according to the present embodiment is applied to a manufacturing process for a semiconductor element, for example, it is possible to transfer a pattern formed on a photoresist to a film made of a silicon-containing material or to remove a film made of a silicon-containing material or a residue present on a film of a non-etching object.

The etching method according to the present embodiment will be described in more detail below.

The etching in the etching method according to the present embodiment is plasma etching. The type of plasma source in the plasma etching is not particularly limited, and any commercially available device may be used. Examples of the plasma include high-frequency discharge plasma such as inductively coupled plasma (ICP) and capacitively coupled plasma (CCP), and microwave discharge plasma such as electron cyclotron resonance plasma (ECRP).

### [Etching Gas]

The etching gas used in the etching method according to the present embodiment contains an acid fluoride and a saturated fluorocarbon, but may contain components other than the acid fluoride and the saturated fluorocarbon, and may further contain at least one of a rare gas and an additive gas.

Examples of the rare gas include helium (He), neon (Ne), argon (Ar), xenon (Xe), and krypton (Kr).

Examples of the additive gas include a nitrogen gas (N₂), a hydrogen gas (H₂), an oxygen gas (O₂), a halogenated hydrocarbon gas (CₘHₙXₒ, where X is any of Cl, Br, or I, m, n, and o are coefficients, and n+o≤2m+2), hydrogen fluoride (HF), hydrogen chloride (HCL), and hydrogen bromide (HBr).

The molar ratio of the acid fluoride to the saturated fluorocarbon in the etching gas ([molar amount of acid fluoride]/[molar amount of saturated fluorocarbon]) is preferably 0.01 or more and 4 or less. The lower limit value of the numerical value range is more preferably 0.05 and still more preferably 0.1. In addition, the upper limit value of the numerical value range is more preferably 3 and still more preferably 2. When the molar ratio of the acid fluoride to the saturated fluorocarbon in the etching gas is within the above-described numerical value range, an etching object can be etched more selectively in comparison to a non-etching object.

The preferred range of the molar ratio of the acid fluoride to the saturated fluorocarbon in the etching gas may be any combination as long as the combination is a combination obtained by combining the above-described upper limit value and the above-described lower limit value. For example, the molar ratio of the acid fluoride to the saturated fluorocarbon in the etching gas is preferably 0.05 or more and 3 or less, and more preferably 0.1 or more and 2 or less.

### [Concentration of Rare Gas]

When a rare gas is contained in the etching gas, plasma may be easily generated. The concentration of the rare gas in the etching gas is preferably more than 0% by volume and 99% by volume or less, more preferably 5% by volume or more and 90% by volume or less, and still more preferably 10% by volume or more and 85% by volume or less. When the concentration of the rare gas contained in the etching gas is within the above-described range, a uniform plasma is easily generated stably, and thus an etching object is easily etched uniformly.

### [Concentration of Additive Gas]

By adding an additive gas to the etching gas, effects such as the increase in the etching rate of the etching object, the suppression of the etching rate of the non-etching object, the formation of the protective film derived from the etching gas on the member to be etched, and the removal of the deposit formed on the member to be etched can be obtained depending on the type of the additive gas.

For example, by adding a halogenated hydrocarbon to the etching gas, it may be possible to suppress the etching of the non-etching object. In addition, by adding a hydrogen halide to the etching gas, it may be possible to improve the etching selectivity ratio. Further, when an oxygen gas or a nitrogen gas is added, it may be easy to remove the deposit formed on the member to be etched.

The optimal value of the concentration of the additive gas in the etching gas varies depending on the desired effect, but for example, it is preferably more than 0% by volume and 99% by volume or less, more preferably 2% by volume or more and 60% by volume or less, and still more preferably 5% by volume or more and 50% by volume or less.

### [Acid Fluoride]

The acid fluoride is a compound having a functional group of *—C(═O) F in the molecule. “*” means any atom or atomic group. The number of carbon atoms contained in the acid fluoride is preferably 5 or less, more preferably 3 or less, and still more preferably 2 or less.

Examples of the acid fluoride include carbonyl fluoride (COF₂), oxalyl fluoride (C₂O₂F₂), trifluoroacetyl fluoride (CF₃COF), formyl fluoride, carbonyl chloride fluoride, acetyl fluoride, 2,2,3,3,3-pentafluoropropanoyl fluoride, 2,2,3,3,4,4,4-heptafluorobutanoyl fluoride, 2,2,3,3,4,4,5,5,5-nonafluoropentanoyl fluoride, 2,2,3,4,4,4-hexafluoro-3-(trifluoromethyl) butanoyl fluoride, and 3,3,3-trifluoro-2,2-bis(trifluoromethyl) propanoyl fluoride. When any of these acid fluorides is used, an etching object can be etched more selectively in comparison to a non-etching object.

Among these acid fluorides, carbonyl fluoride, oxalyl fluoride, or trifluoroacetyl fluoride is preferable, and carbonyl fluoride is more preferable from the viewpoint of ease of availability. One type of the acid fluoride may be used alone, or two or more types thereof may be used in combination.

More specifically, the acid fluoride contained in the etching gas may be at least one of carbonyl fluoride, oxalyl fluoride, and trifluoroacetyl fluoride.

### [Saturated Fluorocarbon]

The fluorocarbon is a compound having a fluorine atom and a carbon atom in the molecule (however, the acid fluoride is excluded). In particular, the fluorocarbon used for the etching gas needs to be a saturated fluorocarbon having no double bond and triple bond.

From the viewpoint of low boiling point and ease of handling as a gas, the saturated fluorocarbon having a higher vapor pressure is preferable. For example, a saturated fluorocarbon having a boiling point of 45° C. or less under atmospheric pressure is preferable, and a saturated fluorocarbon having a boiling point of 30° C. or less under atmospheric pressure is more preferable.

The saturated fluorocarbon may have an element other than a fluorine atom (F) and a carbon atom (C), such as a bromine atom (Br), an iodine atom (I), a hydrogen atom (H), a nitrogen atom (N), an oxygen atom (O), a silicon atom (Si), a sulfur atom(S), a phosphorus atom (P).

Examples of the saturated fluorocarbon include tetrafluoromethane (CF₄), trifluoromethane (CHF₃), difluoromethane (CH₂F₂), fluoromethane (CH₃F), dibromodifluoromethane (CBr₂F₂), trifluoroiodomethane (CF₃I), hexafluoroethane (C₂F₆), octafluoropropane (C₃F₈), hexafluorocyclopropane (C₃F₆), octafluorocyclobutane (C₄F₈), decafluoro-n-butane (C₄F₁₀), decafluoroisobutane (i-C₄F₁₀), tris(trifluoromethyl)amine ((F₃C) 3N), trifluoro (trifluoromethyl) silane ((F₃C) SiF₃), trifluoromethyl sulfur pentafluoride ((F₃C) SF₅), P-trifluoromethyl difluorophosphine ((F₃C) PF₂), and the like. When any of these saturated fluorocarbons is used, an etching object can be etched more selectively in comparison to a non-etching object.

### [Pressure Condition for Etching]

The pressure condition for the etching in the etching method according to the present embodiment is not particularly limited, and it is preferably 0.1 Pa or more and 3 kPa or less, more preferably 0.5 Pa or more and 30 Pa or less, and still more preferably 1 Pa or more and 10 Pa or less. When the pressure condition is in the above-described range, plasma is likely to be stably generated.

For example, by disposing a member to be etched in a chamber, the etching can be carried out while allowing an etching gas to flow in the chamber. The pressure inside the chamber during the flow of the etching gas can be set to 0.1 Pa or more and 3 kPa or less. The flow rate of the etching gas may be set appropriately so that the pressure inside the chamber is maintained at a constant level, according to the size of the chamber and the capacity of an exhaust facility that depressurizes the inside of the chamber.

### [Temperature Condition for Etching]

The temperature condition for the etching in the etching method according to the present embodiment is not particularly limited, and it is preferably set to 0° C. or more and 200° C. or less, more preferably set to 5° C. or more and 170° C. or less, and still more preferably set to 20° C. or more and 150° C. or less.

When the temperature condition is within the above-described range, the acid fluoride can be present in a gaseous state, and the etching rate of the silicon-containing material is likely to be further increased. Here, the temperature of the temperature condition is the temperature of the member to be etched. However, it is also possible to use the temperature of a stage for supporting the member to be etched, where the stage is installed in the chamber of the etching device.

At a temperature of 150° C. or less, a reaction between the acid fluoride and a non-etching object having a carbon-containing material, such as a photoresist, spin-on carbon, or amorphous carbon, does not proceed favorably in both a case where plasma is generated and a case where plasma is not generated. Therefore, when the member to be etched is etched by the etching method according to the present embodiment, it is possible to selectively etch an etching object having a silicon-containing material such as polysilicon, silicon oxide, silicon nitride, or silicon germanium, with almost no etching of a non-etching object.

As a result, the etching method according to the present embodiment can be used for, for example, a method of processing an etching object having a silicon-containing material such as polysilicon, silicon oxide, silicon nitride, or silicon germanium, into a predetermined shape by using a patterned non-etching object as a resist or a mask.

### [Etching Target Object]

The etching object has a silicon-containing material containing silicon (Si), but may be formed of only the silicon-containing material, may have a portion formed of only the silicon-containing material and a portion formed of another material, or may be formed of a mixture of the silicon-containing material and another material.

The silicon-containing material refers to a compound consisting of only silicon and having no other elements, or a compound having silicon and other elements. Examples of the silicon-containing material include polysilicon (poly-Si), silicon oxide (SiOₓ, where x is any coefficient, for example, SiO₂), silicon nitride (Si_{c}N_{d}, where c and d are any coefficients, for example, Si₃N₄), silicon oxynitride (SiOₐN_{b}, where a and b are any coefficients), silicon germanium (Si_{y}Ge_{100-y}, Where y is any number larger than 0 and less than 100), and the like. It is preferable that the silicon-containing material is at least one of silicon oxide, silicon nitride, polysilicon, and silicon germanium. One type of the silicon-containing material may be used alone, or two or more types thereof may be used in combination.

The content of the silicon contained in the silicon-containing material is not particularly limited, and it is preferably 30% by mass or more, more preferably 60% by mass or more, and still more preferably 90% by mass or more. When the silicon-containing material contains silicon and germanium, the total content of the silicon and the germanium, which are contained in the silicon-containing material, is preferably 30% by mole or more.

In addition, the shape of the etching object is not particularly limited, and may be, for example, a plate shape, a foil shape, a film shape, a powder shape, or a lump shape.

### [Non-Etching Object]

The non-etching object has a carbon-containing material having carbon (C), but may be formed of only the carbon-containing material, may have a portion formed of only the carbon-containing material and a portion formed of another material, or may be formed of a mixture of the carbon-containing material and another material.

The carbon-containing material refers to a compound consisting of only carbon and having no other elements, or a compound having carbon and other elements. Examples of the carbon-containing material include amorphous carbon, spin-on carbon, silicon oxide (SiOC) doped with carbon, a photoresist, and the like. One type of the carbon-containing material may be used alone, or two or more types thereof may be used in combination.

The silicon oxide doped with carbon is a compound having a carbon atom, an oxygen atom, and a silicon atom. However, the silicon oxide doped with carbon may further have atoms other than the carbon atom, the oxygen atom, and the silicon atom, and may further have a hydrogen atom, for example.

The content of carbon contained in the carbon-containing material is not particularly limited, and it is preferably 20% by mass or more and 100% by mass or less, more preferably 40% by mass or more and less than 100% by mass, and still more preferably 50% by mass or more and 95% by mass or less. More specifically, in the etching method according to the present embodiment, the carbon contained in the carbon-containing material is preferably 20% by mass or more and 100% by mass or less.

The photoresist means a photosensitive composition in which physical properties such as solubility are changed by light, electron beams, or the like. Examples of the photoresist include a photoresist for a g-ray, a photoresist for an h-ray, a photoresist for an i-ray, a photoresist for KrF, a photoresist for ArF, a photoresist for F2, a photoresist for EUV. The composition of the photoresist is not particularly limited as long as it is generally used in a semiconductor manufacturing step. Examples thereof include a composition containing a polymer synthesized from at least one monomer selected from a chain-like olefin, a cyclic olefin, styrene, vinyl phenol, acrylic acid, methacrylate, epoxy, melamine, and glycol.

In addition, it is possible to use the non-etching object as a resist or a mask for suppressing etching of the etching object by the etching gas. Therefore, it is possible to utilize the etching method according to the present embodiment as a method such as processing an etching object into a predetermined shape by utilizing a patterned non-etching object as a resist or a mask (for example, a film-shaped etching object held by a member to be etched is processed into a predetermined film thickness), and therefore, it is possible to suitably use the etching method for the production of a semiconductor element. In addition, since the non-etching object is hardly etched, it is possible to suppress etching of portions that are originally not to be etched in a semiconductor element, and to prevent the loss of characteristics of the semiconductor element due to etching.

It is possible to remove the non-etching object remaining after patterning by a removal method generally used in a semiconductor element manufacturing step. Examples thereof include ashing with oxidative gases such as oxygen plasma and ozone, and dissolution and removal using chemical liquids such as APM (a mixed liquid of ammonia water and hydrogen peroxide water), SPM (a mixed liquid of sulfuric acid and hydrogen peroxide water), and organic solvents.

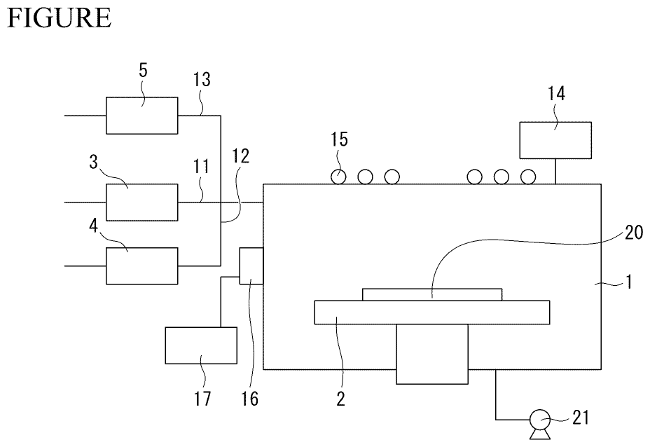

The following describes an example of plasma etching of a polysilicon film, a silicon oxide film, a silicon nitride film, a silicon germanium film, a photoresist film, and a spin-on carbon film, each of which is formed on a surface of a substrate (corresponding to a member to be etched), is carried out using a plasma etching device. The etching device of FIG. 1 is a plasma etching device in which an ICP is used as a plasma source.

The plasma etching device of FIG. 1 includes a chamber 1, where plasma etching is carried out in the inside; a lower electrode 2 that supports a substrate 20 to be subjected to plasma etching, on the inside of the chamber 1; a bias power supply (not illustrated) that applies bias power to the lower electrode 2; an RF coil 15 that forms an electric field and a magnetic field in the inside of the chamber 1, where the electric field and the magnetic field are for forming an etching gas into plasma; a source power supply (not illustrated) that applies source power having a high frequency to the RF coil 15; a vacuum pump 21 that depressurizes the inside of the chamber 1; a pressure gauge 14 that measures pressure in the inside of the chamber 1; a sensor 16 that captures emitted light of plasma generated in association with the generation of plasma; and a spectroscope 17 that spectrally analyzes the emitted light of plasma captured by the sensor 16 to monitor a temporal change in the emitted light of plasma.

A polysilicon film, a silicon oxide film, a silicon nitride film, a silicon germanium film, a photoresist film, or a spin-on carbon film is formed on a surface of the substrate 20. As the sensor 16, for example, a charge-coupled device (CCD) image sensor can be used. However, instead of providing the sensor 16 and the spectroscope 17, a peep window may be provided in the chamber 1, and the inside of the chamber 1 may be visually observed from the peep window to confirm the temporal change of the emitted light of plasma.

The chamber 1 includes an etching gas supply unit that supplies the etching gas to the inside of the chamber 1. The etching gas supply unit has an acid fluoride gas supply unit 3 that supplies an acid fluoride gas, an inert gas supply unit 4 that supplies an inert gas, a saturated fluorocarbon supply unit 5 that supplies a saturated fluorocarbon, an etching gas supply pipe 11 that connects the acid fluoride gas supply unit 3 to the chamber 1, an inert gas supply pipe 12 that connects the inert gas supply unit 4 to an intermediate portion of the etching gas supply pipe 11, and a saturated fluorocarbon supply pipe 13 that connects the saturated fluorocarbon supply unit 5 to an intermediate portion of the etching gas supply pipe 11.

When the acid fluoride gas and the saturated fluorocarbon are supplied to the chamber 1 as the etching gas, the acid fluoride gas is sent from the acid fluoride gas supply unit 3 to the etching gas supply pipe 11, and the saturated fluorocarbon is sent from the saturated fluorocarbon supply unit 5 to the etching gas supply pipe 11 through the saturated fluorocarbon supply pipe 13. Therefore, the acid fluoride gas and the saturated fluorocarbon are mixed in the intermediate portion of the etching gas supply pipe 11 to form a mixed gas, and the mixed gas is allowed to be supplied to the chamber 1 through the etching gas supply pipe 11.

In addition, when a mixed gas of an acid fluoride gas, a saturated fluorocarbon, and an inert gas is supplied as the etching gas, the acid fluoride gas is sent from the acid fluoride gas supply unit 3 to the etching gas supply pipe 11, and the saturated fluorocarbon is sent from the saturated fluorocarbon supply unit 5 to the etching gas supply pipe 11 through the saturated fluorocarbon supply pipe 13, and furthermore, an inert gas is sent from the inert gas supply unit 4 to the etching gas supply pipe 11 through the inert gas supply pipe 12. Therefore, the acid fluoride gas, the saturated fluorocarbon, and the inert gas are mixed in the intermediate portion of the etching gas supply pipe 11 to form a mixed gas, and the mixed gas is allowed to be supplied to the chamber 1 through the etching gas supply pipe 11.

The pressure inside the chamber 1 before supplying the etching gas is not particularly limited as long as the pressure is equal to or less than the supply pressure of the etching gas or a pressure lower than the supply pressure of the etching gas, but for example, the pressure is preferably 10-5 Pa or more and less than 100 kPa, more preferably 0.1 Pa or more and 50 kPa or less, still more preferably 0.3 Pa or more and 15 Pa or less, and particularly preferably 1 Pa or more and 10 Pa or less.

When the plasma etching is carried out using such a plasma etching device, the substrate 20 is placed on the lower electrode 2 disposed inside the chamber 1, the pressure inside the chamber 1 is reduced to, for example, 1 Pa or more and 10 Pa or less by the vacuum pump 21, and then the etching gas is supplied into the chamber 1 by the etching gas supply unit. In addition, when a high frequency (for example, 13.56 MHz) source power is applied to the RF coil 15, an electric field and a magnetic field are formed inside the chamber 1, and thus electrons are accelerated, and the accelerated electrons collide with unsaturated compound molecules in the etching gas to generate new ions and electrons, therefore, discharge occurs and plasma is formed. The generation of the plasma can be confirmed by using the sensor 16 and the spectroscope 17.

When plasma is generated, an etching object formed on the surface of the substrate 20 is etched. The supply amount of the etching gas to the chamber 1 or the concentration of the acid fluoride in the etching gas (mixed gas) can be adjusted by controlling the respective flow rates of the acid fluoride, the inert gas, and the saturated fluorocarbon with mass flow controllers (not illustrated) which are installed in the etching gas supply pipe 11, the inert gas supply pipe 12, and the saturated fluorocarbon supply pipe 13, respectively.

### EXAMPLES

The present disclosure will be described in more detail below with reference to Examples and Comparative Examples.

### Example 1

Seven types of substrates were prepared. More specifically, the first substrate is a substrate obtained by carrying out film formation by forming a polysilicon film having a film thickness of 600 nm on a silicon substrate having a square shape with one side of 1 cm (manufactured by SEIREN KST Corp.). In Table 2 described later, polysilicon may be described as “PSi”.

The second substrate is a substrate obtained by carrying out film formation by forming a silicon oxide (SiO₂) film having a film thickness of 800 nm on a silicon substrate having a square shape with one side of 1 cm (manufactured by SEIREN KST Corp.).

The third substrate is a substrate obtained by carrying out film formation by forming a silicon nitride (Si₃N₄) film having a film thickness of 800 nm on a silicon substrate having a square shape with one side of 1 cm (manufactured by SEIREN KST Corp.).

The fourth substrate is a substrate obtained by carrying out film formation by forming a silicon germanium film having a film thickness of 80 nm on a silicon substrate having a square shape with one side of 1 cm (manufactured by SEIREN KST Corp.). The molar ratio of silicon to germanium ([molar amount of Si]:[molar amount of Ge]) in the silicon germanium is 20:80. In Table 2 described later, the polysilicon of the fourth substrate is described as “Si20Ge80”.

The fifth substrate is a substrate obtained by carrying out film formation by forming a silicon germanium film having a film thickness of 80 nm on a silicon substrate having a square shape with one side of 1 cm (manufactured by SEIREN KST Corp.). The molar ratio of silicon to germanium ([molar amount of Si]:[molar amount of Ge]) in the silicon germanium is 95:5. In Table 2 described later, the polysilicon of the fifth substrate is described as “Si95Ge5”.

The sixth substrate is a substrate obtained by carrying out film formation by forming a photoresist film having a film thickness of 600 nm on a silicon substrate having a square shape with one side of 1 cm. This photoresist film is a photoresist film obtained by carrying out film formation by applying a photoresist TSCR (product name) for an i-ray manufactured by Tokyo Ohka Kogyo Co., Ltd., onto a silicon substrate, and exposing the photoresist to cure the photoresist. The content of carbon contained in the photoresist TSCR (product name) for an i-ray is 67% by mass. In addition, in Table 2 described later, the photoresist may be described as “PR”.

The seventh substrate is a substrate obtained by carrying out film formation by forming a spin-on carbon film having a film thickness of 600 nm on a silicon substrate having a square shape with one side of 1 cm (manufactured by SEIREN KST Corp.). The spin-on carbon film is a spin-on carbon film obtained by forming a film of a spin-on carbon ODL-50, manufactured by Shin-Etsu Chemical Co., Ltd., on a silicon substrate. The content of carbon contained in the spin-on carbon ODL-50 is 80% by mass. In addition, in Table 2 described later, the spin-on carbon may be described as “SOC”. The polysilicon film, the silicon oxide film, the silicon nitride film, and the silicon germanium film are etching objects, and the photoresist film and the spin-on carbon film are non-etching objects.

Plasma etching of the above-described seven types of substrates was carried out using an ICP etching device RIE-200iP manufactured by Samco Inc., which had substantially the same configuration as the plasma etching device of FIG. 1.

The volume of the chamber of the ICP etching device is 46000 cm³, and the etching gas is a mixed gas of a carbonyl fluoride gas, tetrafluoromethane, and argon. The flow rate of the carbonyl fluoride gas was set to 5 sccm, the flow rate of the tetrafluoromethane was set to 10 sccm, and the flow rate of the argon was set to 40 sccm, thereby adjusting the concentration of the carbonyl fluoride in the etching gas to 9% by volume. Here, sccm means a volume flow rate (cm³) standardized under a condition of 0° C. and 1 atm per minute.

As shown in Table 1, after setting the process pressure inside the chamber to 3 Pa, the source power to 300 W, the bias power to 200 W, and the temperature of the substrate to 20° C., plasma etching was carried out while monitoring the flow rate of the carbonyl fluoride gas, the flow rate of the tetrafluoromethane, the flow rate of the argon, the process pressure, the source power, and the bias power at all times, and confirming that there was no difference between each set value and each actual value. The results shown in Table 2.

Table 2 shows the etching rate of the film on each of the first to seventh substrates. When the etching does not proceed and a deposit is generated, it is indicated as “depo”.

In addition, Table 2 shows the etching selectivity ratio ([etching rate of etching object/etching rate of non-etching object]) calculated by dividing the etching rate of the etching object (the polysilicon film, the silicon oxide film, the silicon nitride film, or the silicon germanium film) by the etching rate of the non-etching object (the photoresist film or the spin-on carbon film). When the etching of the non-etching object does not proceed and a deposit is generated, the etching selectivity ratio is indicated as “−”.

TABLE 1

| | Acid fluoride | | Fluorocarbon | | Rare gas | | Etching conditions | | | |
|---|---|---|---|---|---|---|---|---|---|---|
| | | Flow rate | | Flow rate | | Flow rate | Source power | Bias power | Pressure | Temperature |
| | Type | (mL/min) | Type | (mL/min) | Type | (mL/min) | (W) | (W) | (Pa) | (º C.) |
| Ex. 1 | COF₂ | 5 | CF₄ | 10 | Argon | 40 | 300 | 200 | 3 | 20 |
| Ex. 2 | COF₂ | 5 | CF₄ | 10 | Argon | 40 | 300 | 200 | 3 | 60 |
| Ex. 3 | COF₂ | 5 | CF₄ | 10 | Helium | 40 | 300 | 200 | 3 | 20 |
| Ex. 4 | COF₂ | 5 | CF₄ | 10 | Argon | 40 | 300 | 200 | 5 | 20 |
| Ex. 5 | COF₂ | 5 | CF₄ | 10 | Argon | 40 | 1000 | 200 | 3 | 20 |
| Ex. 6 | COF₂ | 5 | CF₄ | 10 | Argon | 40 | 300 | 0 | 3 | 20 |
| Ex. 7 | COF₂ | 150 | CF₄ | 50 | Argon | 100 | 300 | 200 | 3 | 20 |
| Ex. 8 | COF₂ | 5 | C₂F₆ | 10 | Argon | 40 | 300 | 200 | 5 | 20 |
| Ex. 9 | COF₂ | 150 | C₂F₆ | 10 | Argon | 40 | 1000 | 0 | 10 | 40 |
| Ex. 10 | COF₂ | 40 | C₄F₈ | 10 | Helium | 160 | 300 | 200 | 3 | 20 |
| Ex. 11 | COF₂ | 5 | C₄F₈ | 5 | Argon | 45 | 300 | 200 | 3 | 20 |
| Ex. 12 | C₂O₂F₂ | 20 | CF₄ | 60 | Argon | 80 | 300 | 200 | 5 | 40 |
| Ex. 13 | C₂O₂F₂ | 20 | C₂F₆ | 5 | Argon | 80 | 300 | 200 | 1 | 20 |
| Ex. 14 | C₂O₂F₂ | 40 | C₄F₈ | 20 | Argon | 160 | 500 | 50 | 10 | 20 |
| Ex. 15 | C₂F₄O | 6 | CF₄ | 20 | Argon | 30 | 300 | 200 | 1 | 20 |
| Ex. 16 | C₂F₄O | 10 | C₂F₆ | 30 | Argon | 290 | 500 | 200 | 3 | 20 |
| Ex. 17 | C₂F₄O | 30 | C₄F₈ | 12 | Argon | 70 | 300 | 200 | 3 | 20 |
| Comp. Ex. 1 | C₄F₆ | 5 | CF₄ | 10 | Argon | 40 | 300 | 200 | 3 | 20 |
| Comp. Ex. 2 | COF₂ | 5 | Absent | 0 | Argon | 40 | 300 | 200 | 3 | 20 |
| Comp. Ex. 3 | COF₂ | 5 | C₄F₆ | 10 | Argon | 40 | 300 | 200 | 3 | 20 |

TABLE 2

| | Etching rate (nm/min) | | | | | | | | | |
|---|---|---|---|---|---|---|---|---|---|---|
| | | | | | | | | | Spin-on | |
| | Polysilicon | | | | | | Photoresist | | carbon | |
| | (Psi) | SiO₂ | Si₃N₄ | Si20Ge80 | Si95Ge5 | | (PR) | | (SOC) | |
| Ex. 1 | 21.7 | 122.9 | 283.6 | 65.4 | 32.2 | | depo | | depo | |
| Ex. 2 | 62.1 | 210.2 | 357.8 | 121.2 | 82.7 | | depo | | depo | |
| Ex. 3 | 25.8 | 101.7 | 206.2 | 62.6 | 28.1 | | depo | | depo | |
| Ex. 4 | 31.8 | 80.5 | 123.1 | 89.2 | 51.9 | | depo | | depo | |
| Ex. 5 | 42.4 | 136.8 | 227.2 | 112.1 | 63.0 | | depo | | depo | |
| Ex. 6 | 12.1 | 32.7 | 55.8 | 19.1 | 14.6 | | depo | | depo | |
| Ex. 7 | 38.2 | 43.2 | 88.0 | 74.3 | 49.9 | | 0.9 | | 0.9 | |
| Ex. 8 | 10.7 | 98.5 | 174.4 | 58.4 | 35.3 | | depo | | depo | |
| Ex. 9 | 66.3 | 12.2 | 93.2 | 82.2 | 70.8 | | depo | | depo | |
| Ex. 10 | 41.5 | 182.1 | 250.2 | 101.1 | 78.2 | | 4.0 | | 3.6 | |
| Ex. 11 | 16.3 | 67.6 | 72.8 | 51.8 | 33.4 | | 1.5 | | 1.4 | |
| Ex. 12 | 53.0 | 157.3 | 303.3 | 86.4 | 65.0 | | 3.8 | | 3.5 | |
| Ex. 13 | 19.8 | 84.3 | 111.9 | 60.9 | 31.7 | | depo | | depo | |
| Ex. 14 | 13.8 | 53.2 | 78.8 | 49.6 | 26.4 | | 0.5 | | depo | |
| Ex. 15 | 50.2 | 118.4 | 152.2 | 109.2 | 77.7 | | 4.4 | | 4.1 | |
| Ex. 16 | 89.9 | 205.0 | 199.3 | 122.2 | 104.2 | | 7.5 | | 7.4 | |
| Ex. 17 | 23.5 | 103.0 | 138 | 69.1 | 34.8 | | depo | | depo | |
| Comp. Ex. 1 | 19.4 | 67.7 | 44.9 | 50.1 | 39.0 | | 48.2 | | 39.8 | |
| Comp. Ex. 2 | 17.2 | 11.0 | 15.5 | 23.7 | 14.0 | | 28.2 | | 22.6 | |
| Comp. Ex. 3 | depo | 67.0 | 62.0 | depo | depo | | 32.0 | | 15.0 | |
| | Etching selectivity ratio | | | | | | | | | |
| | PSi/ | SiO₂/ | Si₃N₄/ | Si20Ge80/ | Si95Ge5/ | PSi/ | SiO₂/ | Si₃N₄/ | Si20Ge80/ | Si95Ge5/ |
| | PR | PR | PR | PR | PR | SOC | SOC | SOC | SOC | SOC |
| Ex. 1 | — | — | — | — | — | — | — | — | — | — |
| Ex. 2 | — | — | — | — | — | — | — | — | — | — |
| Ex. 3 | — | — | — | — | — | — | — | — | — | — |
| Ex. 4 | — | — | — | — | — | — | — | — | — | — |
| Ex. 5 | — | — | — | — | — | — | — | — | — | — |
| Ex. 6 | — | — | — | — | — | — | — | — | — | — |
| Ex. 7 | 42 | 48 | 98 | 83 | 55 | 42 | 48 | 98 | 83 | 55 |
| Ex. 8 | — | — | — | — | — | — | — | — | — | — |
| Ex. 9 | — | — | — | — | — | — | — | — | — | — |
| Ex. 10 | 10 | 46 | 63 | 25 | 20 | 12 | 51 | 70 | 28 | 22 |
| Ex. 11 | 11 | 45 | 49 | 35 | 22 | 12 | 48 | 52 | 37 | 24 |
| Ex. 12 | 14 | 41 | 80 | 23 | 17 | 15 | 45 | 87 | 25 | 19 |
| Ex. 13 | — | — | — | — | — | — | — | — | — | — |
| Ex. 14 | 28 | 106 | 158 | 99 | 53 | — | — | — | — | — |
| Ex. 15 | 11 | 27 | 35 | 25 | 18 | 12 | 29 | 37 | 27 | 19 |
| Ex. 16 | 12 | 27 | 27 | 16 | 14 | 12 | 28 | 27 | 17 | 14 |
| Ex. 17 | — | — | — | — | — | — | — | — | — | — |
| Comp. Ex. 1 | 0.4 | 1.4 | 0.9 | 1.0 | 0.8 | 0.5 | 1.7 | 1.1 | 1.3 | 1.0 |
| Comp. Ex. 2 | 0.6 | 0.4 | 0.5 | 0.8 | 0.5 | 0.8 | 0.5 | 0.7 | 1.0 | 0.6 |
| Comp. Ex. 3 | 0 | 2.1 | 1.9 | 0 | 0 | 0 | 4.1 | 4.1 | 0 | 0 |

The measurements of the film thickness of the etching object other than the silicon germanium and the film thickness of the non-etching object were carried out using a reflectance spectroscopic film thickness meter F20 manufactured by Filmetrics, INC. The conditions for the film thickness measurement are as follows.

The measurement atmosphere is air, and the measurement temperature is 25° C. The measurement wavelength range is a wavelength range in which the goodness of fit is 0.9 or more, and specifically, the measurement was carried out in the following wavelength range as a guide. More specifically, the wavelength for polysilicon is 500 to 1200 nm, the wavelength for silicon oxide is 300 to 1100 nm, the wavelength for silicon nitride is 500 to 1500 nm, the wavelength for photoresist is 400 to 1000 nm, and the wavelength for spin-on carbon is 400 to 1000 nm.

The film thickness of the silicon germanium was measured using a scanning electron microscope (SU-9000) manufactured by Hitachi High-Tech Corporation. The conditions for the film thickness measurement are as follows.
Pressure inside sample chamber: 4×10⁻⁶ Pa
Measurement temperature: 25° C.
Acceleration voltage: 10.0 kV
Emission current: 15000 nA
Measurement magnification: 400 k times

In addition, the etching rates of the etching object and the non-etching object were calculated by subtracting the film thickness after etching from the film thickness before etching and dividing the resultant thickness difference by the etching time.

### Examples 2 to 17

Plasma etching of the above-described seven types of substrates was carried out in the same manner as in Example 1, except that the type of the etching gas and the etching conditions were different as shown in Table 1. Then, the etching rates of the etching object and the non-etching object were calculated, and the etching selectivity ratio was calculated. The results shown in Table 2.

In the description in Table 1, “C₂F₄O” is trifluoroacetyl fluoride, “C₂F₆” is hexafluoroethane, and “C₄F₈” is octafluorocyclobutane.

### Comparative Example 1

Plasma etching of the above-described seven types of substrates was carried out in the same manner as in Example 1, except that hexafluorobutadiene (C₄F₆) was used instead of the acid fluoride. Then, the etching rates of the etching object and the non-etching object were calculated, and the etching selectivity ratio was calculated. The results shown in Table 2.

### Comparative Example 2

Plasma etching of the above-described seven types of substrates was carried out in the same manner as in Example 1, except that the etching gas was changed to a mixed gas of an acid fluoride and argon (the saturated fluorocarbon was not used). Then, the etching rates of the etching object and the non-etching object were calculated, and the etching selectivity ratio was calculated. The results shown in Table 2.

### Comparative Example 3

Plasma etching of the above-described seven types of substrates was carried out in the same manner as in Example 1, except that the etching gas was changed to a mixed gas of an acid fluoride, hexafluorobutadiene, and argon (the unsaturated fluorocarbon was used instead of the saturated fluorocarbon). Then, the etching rates of the etching object and the non-etching object were calculated, and the etching selectivity ratio was calculated. The results shown in Table 2.

As can be seen from the results of Examples 1 to 6, 8, and 9, when carbonyl fluoride was used as the acid fluoride, a deposit was generated on the non-etching object without etching the non-etching object even when the type of saturated fluorocarbon, the type of rare gas, the source power, the bias power, the pressure inside the chamber, and the temperature of the substrate were changed. From these results, it can be said that the etching selectivity ratio of Examples 1 to 6, 8, and 9 is infinite.

As can be seen from the results of Example 7, even when the flow rate ratio of carbonyl fluoride to tetrafluoromethane was set to 3:1, the etching object was quickly etched, whereas the non-etching object was hardly etched. From this result, it can be seen that in Example 7, the etching object can be etched at a high etching selectivity ratio.

As can be seen from the results of Examples 10 and 11, when octafluorocyclobutane was used as the saturated fluorocarbon, the etching object was etched without any problems, whereas the non-etching object was hardly etched. From these results, it can be seen that in Examples 10 and 11, the etching object can be etched at a high etching selectivity ratio.

As can be seen from the results of Examples 12 to 17, when oxalyl fluoride or trifluoroacetyl fluoride was used as the acid fluoride, the etching object was etched without any problems, whereas the non-etching object was not etched, and a deposit was generated on the non-etching object, or the non-etching object was hardly etched. From these results, it can be seen that in Examples 12 to 17, the etching object can be etched at a high etching selectivity ratio.

As can be seen from the results of Comparative Example 1, when the unsaturated fluorocarbon was used in the etching gas instead of the saturated fluorocarbon, the etching rate of the non-etching object was improved, and thus the numerical value of the etching selectivity ratio was small. From this fact, it was suggested that the unsaturated fluorocarbon is unsuitable as the etching gas.

As can be seen from the results of Comparative Example 2, when an etching gas containing no saturated fluorocarbon was used, the etching rate of the non-etching object was improved, and thus the numerical value of the etching selectivity ratio was small. From this fact, it was suggested that the saturated fluorocarbon is essential as an etching gas.

As can be seen from the results of Comparative Example 3, when an etching gas containing an unsaturated fluorocarbon was used instead of the saturated fluorocarbon, the etching rate of the non-etching object was improved, and thus the selection ratio between the etching object and the non-etching object was decreased. In particular, since a deposit was generated on the polysilicon and the silicon germanium, the etching selectivity ratio was 0.

### REFERENCE SIGNS LIST

1: chamber
2: lower electrode
3: acid fluoride gas supply unit
5: saturated fluorocarbon supply unit
11: etching gas supply pipe
13: saturated fluorocarbon supply pipe
15: RF coil
20: substrate

1. An etching method comprising:
an etching step of carrying out etching by bringing an etching gas containing an acid fluoride and a saturated fluorocarbon into contact with a member to be etched, which has an etching object which is an object to be etched by the etching gas and a non-etching object which is not an object to be etched by the etching gas, in a presence of a plasma, and selectively etching the etching object in comparison to the non-etching object,
wherein the etching object has a silicon-containing material, and
the non-etching object has a carbon-containing material.

2. The etching method according to claim 1, wherein the carbon-containing material contains 20% by mass or more and 100% by mass or less of carbon.

3. The etching method according to claim 1, wherein the silicon-containing material contains silicon and germanium, and
a total content of the silicon and the germanium, which are contained in the silicon-containing material, is 30% by mole or more.

4. The etching method according to claim 1, wherein the silicon-containing material is at least one of silicon oxide, silicon nitride, polysilicon, and silicon germanium.

5. The etching method according to claim 1, wherein an etching selectivity ratio, which is a ratio of an etching rate of the silicon-containing material to an etching rate of the carbon-containing material, is 5 or more.

6. The etching method according to claim 1, wherein the acid fluoride is at least one of carbonyl fluoride, oxalyl fluoride, and trifluoroacetyl fluoride.

7. The etching method according to claim 2, wherein the silicon-containing material contains silicon and germanium, and
a total content of the silicon and the germanium, which are contained in the silicon-containing material, is 30% by mole or more.

8. The etching method according to claim 2, wherein the silicon-containing material is at least one of silicon oxide, silicon nitride, polysilicon, and silicon germanium.

9. The etching method according to claim 2, wherein an etching selectivity ratio, which is a ratio of an etching rate of the silicon-containing material to an etching rate of the carbon-containing material, is 5 or more.

10. The etching method according to claim 2, wherein the acid fluoride is at least one of carbonyl fluoride, oxalyl fluoride, and trifluoroacetyl fluoride.
